(19) United States
(12) Patent Application Publication
(10) Pub. No.: US 2025/0199417 A1
(43) Pub. Date: Jun. 19, 2025

(54) LEARNING CONTROL SYSTEM AND METHOD FOR ULTRA-PRECISION LITHOGRAPHIC APPARATUS BASED ON UNCERTAINTY COMPENSATION

(71) Applicant: Harbin Institute of Technology, Harbin (CN)

(72) Inventors: Fazhi SONG, Harbin (CN); Pengyu SUN, Harbin (CN); Aichen WU, Harbin (CN); Yang LIU, Harbin (CN); Jiubin TAN, Harbin (CN)

(73) Assignee: Harbin Institute of Technology, Harbin (CN)

(21) Appl. No.: 19/063,189

(22) Filed: Feb. 25, 2025

(30) Foreign Application Priority Data
Feb. 26, 2024 (CN) 202410208941.8

(51) Int. Cl. G03F 7/00; G05B 13/02

(52) U.S. Cl. CPC G03F 7/705; G03F 7/70358; G03F 7/70508; G03F 7/70525; G05B 13/0265

(57) ABSTRACT

A learning control system includes a movement trajectory generation unit, a learning control unit, a feedback control unit, and an uncertainty compensation unit. The movement trajectory generation unit includes a movement trajectory generator; the movement trajectory generator is configured to generate a reference movement trajectory; a position measured signal is subtracted from the reference movement trajectory to obtain a position error signal which is input to the learning control unit; the learning control unit is configured to generate a feed-forward signal which is added with the position error signal to obtain a corrected error signal; and the corrected error signal is input to the feedback control unit; the feedback control unit includes a feedback controller configured to generate a feedback control quantity which is input to the uncertainty compensation unit; and the uncertainty compensation unit is configured to generate the position measured signal.

### CROSS-REFERENCE TO RELATED APPLICATIONS

This application claims priority to Chinese Patent Application No. 202410208941.8 with a filing date of Feb. 26, 2024. The content of the aforementioned application, including any intervening amendments thereto, is incorporated herein by reference.

### TECHNICAL FIELD

The present disclosure belongs to the technical field of ultra-precision apparatus manufacturing, relates to a system and method for controlling an ultra-precision lithographic apparatus, and particularly relates to a learning control system and method for an ultra-precision lithographic apparatus based on uncertainty compensation.

### BACKGROUND

With the pursuit of Moore's Law, semiconductor manufacturers are imposing higher and higher requirements on the yield and quality of chips. This is manifested in the lithographic apparatus that must have high dynamics and high accuracy. The shorter transition time of the movement mechanism of the lithographic apparatus from an accelerating section to a uniform scanning exposure section indicates a larger number of chips exposed in unit time, and a higher yield. The smaller tracking error of the movement mechanism in the scanning exposure section means higher imaging quality and higher quality of the chips. Hence, researching advanced control methods, and improving control accuracy of the ultra-precision lithographic apparatus are of great significance to improve performance of the chips.

Due to repetitive nature of the scanning exposure process, an iterative learning control method is widely applied to movement control of the ultra-precision lithographic apparatus. However, the conventional learning control method has two problems: (1) The design of the learning gain is dependent on a mathematical model of the control object. The higher accuracy of the model means a higher rate of convergence and better convergence performance of the control method. However, for the complex ultra-precision lithographic apparatus, due to the flexible modality and complex dynamics, the accurate mathematical model is obtained hardly, and the modeling cost is high. (2) The non-repetitive disturbances are not suppressed, but are amplified possibly, by the iterative learning control method. The external random disturbances will reduce performance of the iterative learning control method. The above two factors restrict the actual application of the iterative learning control method in the ultra-precision lithographic apparatus.

### SUMMARY OF PRESENT INVENTION

In order to solve the problem that the existing learning control method is strongly dependent on the model and sensitive to the non-repetitive disturbance, and thus is restricted in the ultra-precision lithographic apparatus, the present disclosure provides a learning control system and method for an ultra-precision lithographic apparatus based on uncertainty compensation. The present disclosure can effectively reduce the influence of the model uncertainty on learning performance, can effectively compensate the external random disturbance, and has a simple design and a strong practical application value.

The objective of the present disclosure is achieved by the following technical solutions:
A learning control system for an ultra-precision lithographic apparatus based on uncertainty compensation includes a movement trajectory generation unit S₁, a learning control unit S₂, a feedback control unit S₃, and an uncertainty compensation unit S₄; the movement trajectory generation unit S₁ includes a movement trajectory generator Cᵣ; the movement trajectory generator Cᵣ is configured to generate a reference movement trajectory y_{d}(t); a position measured signal y_{ε,k}(t) is subtracted from the reference movement trajectory y_{d}(t) to obtain a position error signal eₖ(t); and the position error signal eₖ(t) is input to the learning control unit S₂; the learning control unit S₂ includes a learning controller C_{L} and an iterative backward shift operator z⁻¹; the position error signal eₖ(t) and a feed-forward signal e_{ff,k}(t) are input to the learning controller C_{L}; the learning controller C_{L} is configured to generate a (k+1)th feed-forward signal e_{ff,k+1}(t); the (k+1)th feed-forward signal e_{ff,k+1}(t) is input to the iterative backward shift operator z⁻¹; the iterative backward shift operator z⁻¹ is configured to generate the k th feed-forward signal e_{ff,k}(t); the feed-forward signal e_{ff,k}(t) and the position error signal eₖ (t) are added together to obtain a corrected error signal e_{fb,k}(t); and the corrected error signal e_{fb,k}(t) is input to the feedback control unit S₃; the feedback control unit S₃ includes a feedback controller C_{fb}; the feedback controller C_{fb} is configured to generate a feedback control quantity u_{fb,k}(t); and the feedback control quantity u_{fb,k}(t) is input to the uncertainty compensation unit S₄; the uncertainty compensation unit S₄ includes a nominal mass module [symbol] , a lithographic apparatus P, an extended state observer Cₑₛₒ, an external disturbance signal f_{d,k}(t), and a measured noise signal εₖ(t); an uncertainty estimated signal [symbol] (t) is subtracted from the feedback control quantity u_{fb,k}(t) to obtain a compensated control quantity u_{mi,k}(t); the compensated control quantity u_{mi,k}(t) is input to the nominal mass module [symbol] ; the nominal mass module [symbol] is configured to generate a corrected control quantity u_{mo,k}(t); the corrected control quantity u_{mo,k}(t) and the external disturbance signal f_{d,k}(t) are added together to obtain a total input signal u_{P,k}(t); the total input signal u_{P,k}(t) is input to the lithographic apparatus P; the lithographic apparatus P is configured to generate an actual position signal y_{P,k}(t); the actual position signal y_{P,k}(t) and the measured noise signal εₖ(t) are added together to obtain the position measured signal y_{ε,k}(t); the position measured signal y_{ε,k}(t) and the corrected control quantity u_{mo,k}(t) are input to the extended state observer Cₑₛₒ; and the extended state observer Cₑₛₒ is configured to generate the uncertainty estimated signal [symbol] (t); and the subscript k represents a number of iterative experiments, k≥1, and t represents time.

A learning control method for an ultra-precision lithographic apparatus based on uncertainty compensation with the system includes the following steps:
step 1, performing Fourier transform on the k th position error signal eₖ (t) and the k th feed-forward signal e_{ff,k}(t) to obtain a k th frequency-domain position error signal eₖ(jw) and a k th frequency-domain feed-forward signal e_{ff,k}(jw), specifically:

$$\{ \begin{matrix}{e}_{k} ( jw ) = F \{ {e}_{k} ( t ) \} \\ {e}_{ff , k} ( jw ) = F \{ {e}_{ff , k} ( t ) \}\end{matrix}$$

where F represents the Fourier transform, j represents an imaginary unit, and w represents an angular frequency;
step 2, obtaining a (k+1)th frequency-domain feed-forward signal e_{ff,k+1}(jw) from the k th frequency-domain position error signal eₖ(jw) and the k th frequency-domain feed-forward signal e_{ff,k}(jw), specifically:

$${e}_{ff , k + 1} ( jw ) = {e}_{ff , k} ( jw ) + α {G}_{eso}^{- 1} ( jw ) {e}_{k} ( jw )$$

where

$${\overline{G}}_{eso} ( jw ) = \frac{{\overline{P}}_{eso} ( s ) {C}_{fb} ( s )}{1 + {\overline{P}}_{eso} ( s ) {C}_{fb} ( s )} {\vert}_{s = jw} ,$$

Gₑₛₒ⁻¹(jw) represents an inverse of G̅ₑₛₒ(jw),

$${\overline{P}}_{eso} ( s ) = \frac{1}{{s}^{2}} ,$$

C_{fb}(s) is a transfer function of the feedback controller C_{fb}, s represents a Laplace operator, and α∈(0 1) is a learning coefficient, which may be designed as a constant, and may also be designed adaptively;

step 3, performing inverse Fourier transform on the (k+1)th frequency-domain feed-forward signal e_{ff,k+1}(jw) to obtain the (k+1)th feed-forward signal e_{ff,k+1}(t), specifically:

$${e}_{ff , k + 1} ( t ) = {F}^{- 1} \{ {e}_{ff , k + 1} ( jw ) \}$$

where F⁻¹ represents the inverse Fourier transform; and

step 4, calculating, by the extended state observer Cₑₛₒ, the uncertainty estimated signal [symbol] (t) according to the corrected control quantity u_{mo,k}(t) and the position measured signal y_{ε,k}(t) by:

$$\{ \begin{matrix}{u}_{mo , k} ( s ) = L \{ {u}_{mo , k} ( t ) \} \\ {y}_{ε , k} ( s ) = L \{ {y}_{ε , k} ( t ) \} \\ ( s ) = \frac{- \frac{1}{\hat{m}}}{{( \frac{s}{{w}_{o}} + 1 )}^{3}} {u}_{mo , k} ( s ) + \frac{{s}^{2}}{{( \frac{s}{{w}_{o}} + 1 )}^{3}} {y}_{ε , k} ( s ) \\ ( t ) = {L}^{- 1} \{ ( s ) \}\end{matrix}$$

where L represents Laplace transform, L⁻¹ represents inverse Laplace transform, and wₒ is a bandwidth of the extended state observer Cₑₛₒ.

Compared with the prior art, the present disclosure has the following advantages:

The present disclosure is realized only with the approximate mass of the control object and without the accurate model of the control object. By introducing the extended state observer on the basis of conventional learning control, the present disclosure approximately corrects the control object as a two-order system with a unit mass. The present disclosure compensates the model uncertainty and suppresses the external random disturbance at the same time, improves the control accuracy, and has a strong engineering application value.

### BRIEF DESCRIPTION OF THE DRAWINGS

FIG. 1 is a topological diagram of a learning control system for an ultra-precision lithographic apparatus based on uncertainty compensation according to the present disclosure;

FIG. 2 illustrates a reference movement trajectory according to an embodiment;

FIG. 3 illustrates an effect of a method according to an embodiment of the present disclosure;

FIG. 4 illustrates comparison between a method of the present disclosure and an existing method based on an inaccurate model according to an embodiment; and

FIG. 5 illustrates comparison between a method of the present disclosure and an existing method based on an accurate model according to an embodiment.

### DETAILED DESCRIPTION OF THE EMBODIMENTS

The technical solutions of the present disclosure are further described below with reference to the drawings, but the present disclosure is not limited thereto. Any modification or equivalent replacement for the technical solutions of the present disclosure made without departing from the spirit and scope of the technical solutions of the present disclosure should fall within the protection scope of the present disclosure.

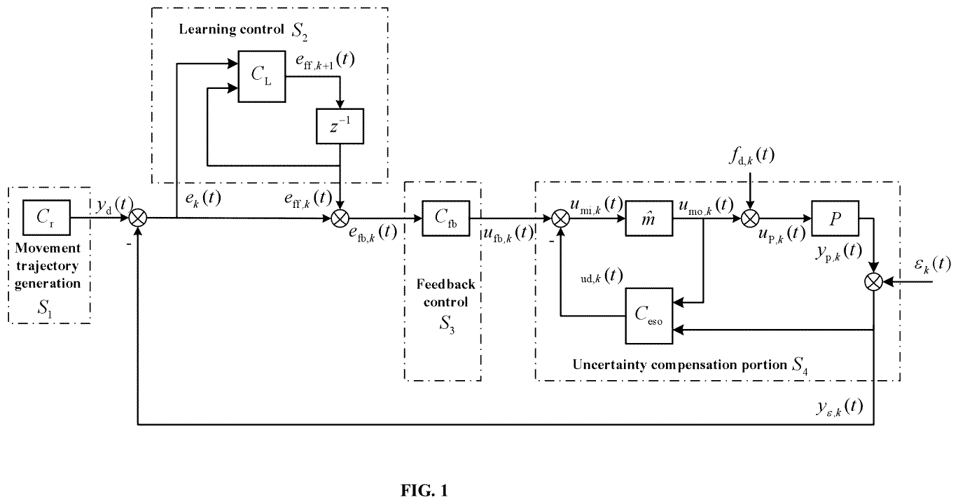

The present disclosure provides a learning control system for an ultra-precision lithographic apparatus based on uncertainty compensation. As shown in FIG. 1, the learning control system includes a movement trajectory generation unit S₁, a learning control unit S₂, a feedback control unit S₃, and an uncertainty compensation unit S₄.

The movement trajectory generation unit S₁ includes a movement trajectory generator Cᵣ. The movement trajectory generator Cᵣ is configured to generate a reference movement trajectory y_{d}(t). A position measured signal y_{ε,k}(t) is subtracted from the reference movement trajectory y_{d}(t) to obtain a position error signal eₖ(t). The position error signal eₖ(t) is input to the learning control unit S₂. The learning control unit S₂ is configured to generate a feed-forward signal e_{ff,k}(t). The feed-forward signal e_{ff,k}(t) and the position error signal eₖ(t) are added together to obtain a corrected error signal e_{fb,k}(t). The corrected error signal e_{fb,k}(t) is input to the feedback control unit S₃. The feedback control unit S₃ includes a feedback controller C_{fb}. The feedback controller C_{fb} is configured to generate a feedback control quantity u_{fb,k}(f). The feedback control quantity u_{fb,k}(t) is input to the uncertainty compensation unit S₄. The uncertainty compensation unit S₄ is configured to generate the position measured signal y_{ε,k}(t).

The learning control unit S₂ includes a learning controller C_{L} and an iterative backward shift operator z⁻¹. The position error signal eₖ(t) and the feed-forward signal e_{ff,k}(t) are input to the learning controller C_{L}. The learning controller C_{L} is configured to generate a (k+1)th feed-forward signal e_{ff,k+1}(t). The (k+1)th feed-forward signal e_{ff,k+1}(t) is input to the iterative backward shift operator z⁻¹. The iterative backward shift operator z⁻¹ is configured to generate the k th feed-forward signal e_{ff,k}(t).

The uncertainty compensation unit S₄ includes a nominal mass module [symbol] , a lithographic apparatus P, an extended state observer Cₑₛₒ, an external disturbance signal f_{d,k}(t), and a measured noise signal εₖ(t). An uncertainty estimated signal [symbol] (t) is subtracted from the feedback control quantity u_{fb,k}(t) to obtain a compensated control quantity u_{mi,k}(t). The compensated control quantity u_{mi,k}(t) is input to the nominal mass module [symbol] . The nominal mass module [symbol] is configured to generate a corrected control quantity u_{mo,k}(t). The corrected control quantity u_{mo,k}(t) and the external disturbance signal f_{d,k}(t) are added together to obtain a total input signal u_{P,k}(t). The total input signal u_{P,k}(t) is input to the lithographic apparatus P. The lithographic apparatus P is configured to generate an actual position signal y_{P,k}(t). The actual position signal y_{P,k}(t) and the measured noise signal εₖ(t) are added together to obtain a position measured signal y_{ε,k}(t). The position measured signal y_{ε,k}(t) and the corrected control quantity u_{mo,k}(t) are input to the extended state observer Cₑₛₒ. The extended state observer Cₑₛₒ is configured to generate the uncertainty estimated signal [symbol] (t).

The subscript k represents a number of iterative experiments, k≥1, and t represents time.

The present disclosure provides a learning control method for an ultra-precision lithographic apparatus based on uncertainty compensation. According to the above system, the learning controller C_{L} is configured to obtain the (k+1)th feed-forward signal e_{ff,k+1}(t) according to the k th position error signal eₖ(t) and the k th feed-forward signal e_{ff,k}(t). The control method includes the following steps:

In step 1, Fourier transform is performed on the k th position error signal eₖ(t) and the k th feed-forward signal e_{ff,k}(t) to obtain a k th frequency-domain position error signal eₖ(jw) and a k th frequency-domain feed-forward signal e_{ff,k}(jw), specifically:

$$\{ \begin{matrix}{e}_{k} ( jw ) = F \{ {e}_{k} ( t ) \} \\ {e}_{ff , k} ( jw ) = F \{ {e}_{ff , k} ( t ) \}\end{matrix}$$

where F represents the Fourier transform, j represents an imaginary unit, and W represents an angular frequency.

In step 2, a (k+1)th frequency-domain feed-forward signal e_{ff,k+1}(jw) is obtained from the k th frequency-domain position error signal eₖ (jw) and the k th frequency-domain feed-forward signal e_{ff,k}(jw), specifically:

$${e}_{ff , k + 1} ( jw ) = {e}_{ff , k} ( jw ) + α {G}_{eso}^{- 1} ( jw ) {e}_{k} ( jw )$$

where

$${\overline{G}}_{eso} ( jw ) = \frac{{\overline{P}}_{eso} ( s ) {C}_{fb} ( s )}{1 + {\overline{P}}_{eso} ( s ) {C}_{fb} ( s )} {\vert}_{s = jw} ,$$

Gₑₛₒ⁻¹(jw) represents an inverse of G̅ₑₛₒ(jw),

$${\overline{P}}_{eso} ( s ) = \frac{1}{{s}^{2}} ,$$

C_{fb}(s) is a transter function of the feedback controller C_{fb}, s represents a Laplace operator, and α∈(0 1) is a learning coefficient, which may be designed as a constant, and may also be designed adaptively.

In step 3, inverse Fourier transform is performed on the (k+1)th frequency-domain feed-forward signal e_{ff,k+1}(jw) to obtain the (k+1)th feed-forward signal e_{ff,k+1}(t), specifically:

$${e}_{ff , k + 1} ( t ) = {F}^{- 1} \{ {e}_{ff , k + 1} ( jw ) \}$$

where F⁻¹ represents the inverse Fourier transform.

In step 4, the extended state observer Cₑₛₒ calculates the uncertainty estimated signal [symbol] (t) according to the corrected control quantity u_{mo,k}(t) and the position measured signal y_{ε,k}(t) by:

$$\{ \begin{matrix}{u}_{mo , k} ( s ) = L \{ {u}_{mo , k} ( t ) \} \\ {y}_{ε , k} ( s ) = L \{ {y}_{ε , k} ( t ) \} \\ ( s ) = \frac{- \frac{1}{\hat{m}}}{{( \frac{s}{{w}_{o}} + 1 )}^{3}} {u}_{mo , k} ( s ) + \frac{{s}^{2}}{{( \frac{s}{{w}_{o}} + 1 )}^{3}} {y}_{ε , k} ( s ) \\ ( t ) = {L}^{- 1} \{ ( s ) \}\end{matrix}$$

where L represents Laplace transform, L⁻¹ represents inverse Laplace transform, and wₒ is a bandwidth of the extended state observer Cₑₛₒ.

### EXAMPLE

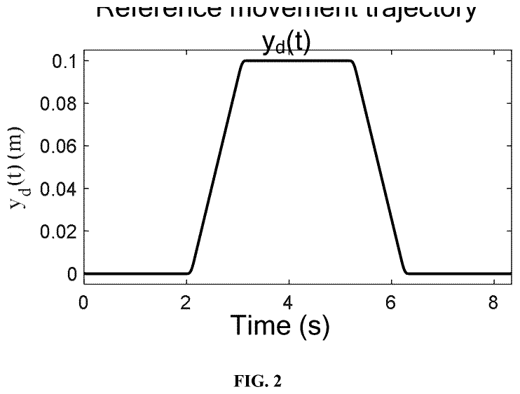

In the example, the movement trajectory generator Cᵣ is a five-order S-shaped movement trajectory generator, and the generated reference movement trajectory y_{d}(t) is as shown in FIG. 2. The transfer function C_{fb}(s) of the feedback controller C_{fb} and the transfer function P(s) of the lithographic apparatus P are set forth hereinafter respectively:

$${C}_{fb} ( s ) = \frac{7.549 {s}^{2} + 1413 s + 5.173 \times {10}^{4}}{0.000019 {s}^{2} + 0.02002 s} ,$$

$$P ( s ) = \frac{1}{12 {s}^{2}} + \frac{0.013}{{s}^{2} + 100.53 s + {( 2 π \times 200 )}^{2}} + \frac{0.0023}{{s}^{2} + 133.91 s + {( 2 π \times 592 )}^{2}} , .$$

The nominal mass module [symbol] is [symbol] =11, and the learning coefficient α in the learning controller C_{L} is α=0.7. The measured noise signal εₖ(t) is a white noise signal with a variance of 0.1*10⁻⁹ and a mean of 0. The disturbance signal f_{d,k}(t) is a white noise signal with a variance of 1 and a mean of 0. The bandwidth wₒ of the extended state observer Cₑₛₒ is wₒ=2π×600.

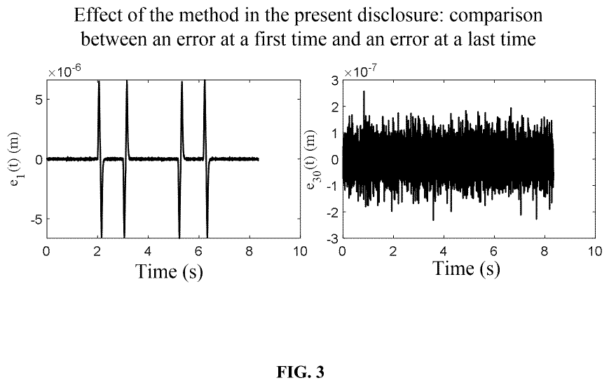

Thirty iterative experiments are made according to the steps in the specific implementation, with simulation results as shown in FIG. 3. It can be observed that through multiple iterations, the learning control system and method for an ultra-precision lithographic apparatus based on uncertainty compensation provided by the present disclosure can greatly reduce the position error.

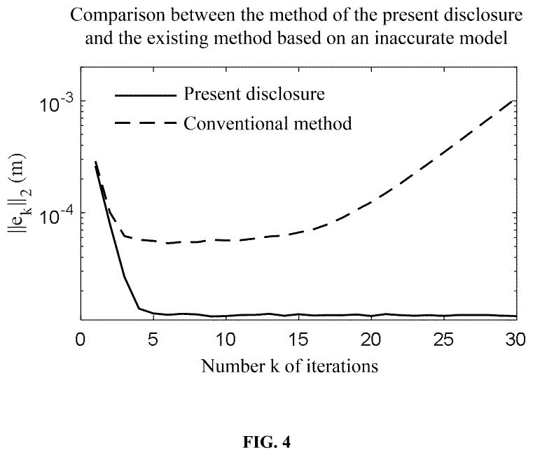

In order to describe an effect of comparison between the method of the present disclosure and the existing iterative learning control method based on an inverse model, FIG. 4 gives comparison between the method of the present disclosure and the existing method when the model in the existing method is inaccurate (same model information as the present disclosure is used, namely only the nominal mass [symbol] =11 of the lithographic apparatus P is used, and the lithographic apparatus P has an estimation model of

$${P}_{m} ( s ) = \frac{1}{11 {s}^{2}} ) .$$

It can be observed that after several iterations, the existing method exhibits a divergence phenomenon. This is largely due to the fact that the estimation model Pₘ(s) is greatly different from the actual model P(s) to violate related conditions for convergence of the iterative learning, and the corresponding position error signal at the resonance frequency is accumulated gradually. The extended state observer Cₑₛₒ introduced in the method of the present disclosure is used to correct the control object as a double integration process with a unit mass. This greatly compensates the model uncertainty, and ensures the convergence of the learning controller C_{L}.

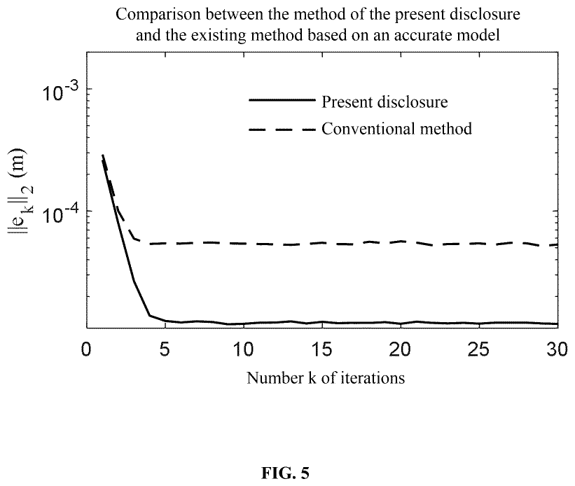

FIG. 5 gives comparison between the existing method based on an accurate model (the lithographic apparatus P has an estimation model of Pₘ(s)=P(s)) and the method of the present disclosure. After the accurate model is used, the existing method realizes convergence without the divergence phenomenon, but still has a large error after the convergence as compared with the method of the present disclosure. The existing method cannot suppress the random disturbance. However, the extended state observer Cₑₛₒ in the method of the present disclosure not only can compensate the model uncertainty, but also can suppress the random disturbance in the bandwidth of wₒ to some extent to achieve more excellent control performance.

As can be seen from FIG. 3 to FIG. 5, the learning control system and method for an ultra-precision lithographic apparatus based on uncertainty compensation provided by the present disclosure compensate the model uncertainty and suppress the random disturbance at the same time with less model information (the lithographic apparatus P has the nominal mass of [symbol] ), and achieve higher control accuracy.

What is claimed is:

1. A learning control system for an ultra-precision lithographic apparatus based on uncertainty compensation, comprising a movement trajectory generation unit (S₁), a learning control unit (S₂), a feedback control unit (S₃), and an uncertainty compensation unit (S₄), wherein
the movement trajectory generation unit (S₁) comprises a movement trajectory generator (Cᵣ); the movement trajectory generator Cᵣ is configured to generate a reference movement trajectory (y_{d}(t)); a position measured signal (y_{ε,k}(t)) is subtracted from the reference movement trajectory (y_{d}(t)) to obtain a position error signal (eₖ(t)); and the position error signal (eₖ(t)) is input to the learning control unit (S₂);
the learning control unit S₂ comprises a learning controller (C_{L}) and an iterative backward shift operator (z⁻¹); the position error signal (eₖ(t)) and a k th feed-forward signal (e_{ff,k}(t)) are input to the learning controller (C_{L}); the learning controller (C_{L}) is configured to generate a (k+1)th feed-forward signal (e_{ff,k+1}(t)); the (k+1)th feed-forward signal (e_{ff,k+1}(t)) is input to the iterative backward shift operator (z⁻¹); the iterative backward shift operator (z⁻¹) is configured to generate the kth feed-forward signal (e_{ff,k}(t); the kth feed-forward signal (e_{ff,k}(t)) and the position error signal (eₖ(t)) are added together to obtain a corrected error signal (e_{fb,k}(t)); and the corrected error signal (e_{ff,k}(t)) is input to the feedback control unit (S₃);
the feedback control unit (S₃) comprises a feedback controller (C_{fb}); the feedback controller (C_{fb}) is configured to generate a feedback control quantity (u_{fb,k}(t)); and the feedback control quantity (u_{ff,k}(t)) is input to the uncertainty compensation unit (S₄);
the uncertainty compensation unit (S₄) comprises a nominal mass module ( [symbol] ), a lithographic apparatus (P), an extended state observer (Cₑₛₒ), an external disturbance signal (f_{d,k}(t)), and a measured noise signal (εₖ(t)); an uncertainty estimated signal ( [symbol] (t)) is subtracted from the feedback control quantity (u_{fb,k}(t)) to obtain a compensated control quantity (u_{mi,k}(t)); the compensated control quantity (u_{mi,k}(t)) is input to the nominal mass module [symbol] ; the nominal mass module ( [symbol] ) is configured to generate a corrected control quantity (u_{mo,k}(t)); the corrected control quantity (u_{mo,k}(t)) and the external disturbance signal f_{d,k}(t) are added together to obtain a total input signal (u_{P,k}(t)); the total input signal u_{P,k}(t) is input to the lithographic apparatus (P); the lithographic apparatus P is configured to generate an actual position signal (y_{P,k}(t)); the actual position signal (y_{P,k}(t)) and the measured noise signal (εₖ(t)) are added together to obtain the position measured signal (y_{ε,k}(t)); the position measured signal (y_{ε,k}(t)) and the corrected control quantity (u_{mo,k}(t)) are input to the extended state observer (Cₑₛₒ); and the extended state observer (Cₑₛₒ) is configured to generate the uncertainty estimated signal ( [symbol] (t)); and
subscript k represents a number of iterative experiments, k≥1, and t represents time.

2. A learning control method for an ultra-precision lithographic apparatus based on uncertainty compensation with the system according to claim 1, comprising the following steps:
step 1, performing Fourier transform on the k th position error signal (eₖ(t)) and the kth feed-forward signal (e_{ff,k}(t) to obtain a kth frequency-domain position error signal (eₖ(jw)) and a k th frequency-domain feed-forward signal (e_{ff,k}(jw)), specifically:
$$\{ \begin{matrix}{e}_{k} ( j w ) = F \{ {e}_{k} ( t ) \} \\ {e}_{ff , k} ( j w ) = F \{ {e}_{ff , k} ( t ) \}\end{matrix}$$
wherein F represents the Fourier transform, J represents an imaginary unit, and W represents an angular frequency;
step 2, obtaining a (k+1)th frequency-domain feed-forward signal (e_{ff,k+1}(jw) according to the k th frequency-domain position error signal (eₖ(jw)) and the k th frequency-domain feed-forward signal (e_{ff,k}(jw)), specifically:
$${e}_{ff , k + 1} ( jw ) = {e}_{ff , k} ( j w ) + α {G}_{e s o}^{- 1} ( j w ) {e}_{k} ( j w )$$
wherein
$${\overline{G}}_{e s o} ( j w ) = \frac{{\overline{P}}_{e s o} ( s ) {C}_{fb} ( s )}{1 + {\overline{P}}_{e s o} ( s ) {C}_{fb} ( s )} {\vert}_{s = jw} ,$$
G⁻¹ₑₛₒ(jw) represents an inverse of G̅ₑₛₒ(jw),
$${\overline{P}}_{e s o} ( s ) = \frac{1}{{s}^{2}} , \qquad {C}_{fb} ( s )$$
is a transfer function of the feedback controller (C_{fb}), s represents a Laplace operator, and α∈(0 1) is a learning coefficient;
step 3, performing inverse Fourier transform on the (k+1)th frequency-domain feed-forward signal (e_{ff,k+1}(jw) to obtain the (k+1)th feed-forward signal (e_{ff,k+1}(t), specifically:
$${e}_{ff , k + 1} ( t ) = {F}^{- 1} \{ {e}_{ff , k + 1} ( j w ) \}$$
wherein F⁻¹ represents the inverse Fourier transform; and
step 4, calculating, by the extended state observer (Cₑₛₒ), the uncertainty estimated signal ( [symbol] (t)) according to the corrected control quantity (u_{mo,k}(t)) and the position measured signal (y_{ε,k}(t)) by:
$$\{ \begin{matrix}{u}_{mo , k} ( s ) = L \{ {u}_{mo , k} ( t ) \} \\ {y}_{ε , k} ( s ) = L \{ {y}_{ε , k} ( t ) \} \\ ( s ) = \frac{- \frac{1}{\hat{m}}}{{( \frac{s}{{w}_{o}} + 1 )}^{3}} {u}_{mo , k} ( s ) + \frac{{s}^{2}}{{( \frac{s}{{w}_{o}} + 1 )}^{3}} {y}_{ε , k} ( s ) \\ ( t ) = {L}^{- 1} \{ ( s ) \}\end{matrix}$$
wherein L represents Laplace transform, L⁻¹ represents inverse Laplace transform, and wₒ is a bandwidth of the extended state observer (Cₑₛₒ).
